(19) United States
(12) Patent Application Publication
(10) Pub. No.: US 2013/0294618 A1
(43) Pub. Date: Nov. 7, 2013

(54) SOUND REPRODUCING INTELLECTUAL SYSTEM AND METHOD OF CONTROL THEREOF

(71) Applicant: Mikhail LYUBACHEV, St. Petersburg (RU)

(72) Inventor: Mikhail LYUBACHEV, St. Petersburg (RU)

(21) Appl. No.: 13/464,993

(22) Filed: May 6, 2012

(51) Int. Cl. H03G 3/00; H04B 3/00

(52) U.S. Cl. 381/80

(57) ABSTRACT

The invention relates to the method and devices of sound volume management and control in the attended areas. According to the proposed method and system variants the sound reproducing system comprises: sounding mode appointment device, central station for audio signal transmittance; one or more peripheral stations for audio signal reception and playback; appliance for listener's location recognition; computing device for performing calculation concerning sounding parameters at the points of each listener's location and for performing calculation of controlling parameters for system tuning. The system can be operated wirelessly and can compose a local network.

### THE FIELD OF THE INVENTION

The present invention relates generally to cybernetics and particularly to the sphere of sound reproducing devices controlling processes automation. A plurality of sound reproducing devices are mainly permanently installed in our rooms, home theatres, private or public cinema halls, or concert halls and in the open air.

### PRIOR ART

Systems for volume control in the stereo- (stereophonic, two-channel) and quadro- (quadrophonic, four-channel) audio systems are known in the art. Known systems allow user to examine the volume level within the room in the attended object (e.g. object accompanied with a mobile control device) neighborhood and automatically control loudspeakers volume level (patent of Korea No. KR2008075351).

Using audio-sensors along with electric signals forming appliance, the system performs the automatic loudspeakers volume control in accordance with appointed mode.

The disadvantage of the system lies in that it can be tuned up only on particular point where the control device is located.

This system is taken as prototype.

The technical result of the present invention comprises increasing of the audio system customer (listener) convenience, possibility of attending a plurality of persons simultaneously, independence from the control device location.

The known solutions fail to achieve the declared advantages.

### BRIEF DESCRIOTION OF DRAWINGS

FIG. 1 shows the logical diagram of the proposed method.

FIG. 2 shows the diagram of the solitary device according to variant 1.

FIG. 3 shows the diagram of the cluster-type (network) device according to variant 2 (comprising central station (base device) and peripheral stations (subordinate devices).

FIG. 4 shows the diagram of the cluster-type (network) device according to variant 3 (comprising peer devices).

FIG. 5 shows the diagram of the cluster-type (peer network) device when each member device comprising different set of components.

FIG. 6 shows the diagram of the cluster-type (network) device for the case of attending a plurality of listeners. The attended area bounding zone is shown.

FIGS. 7a and 7b illustrates how the device turns the sound source direction impression at the listener's turn (e.g. 90° to the left). It reappoints the sound channel of each loudspeaker at the listener's turn (FIG. 7b).

FIG. 8 illustrates how the device changes each loudspeaker's appointment at the listener's leaving the area bounded by loudspeakers. Currently it changes the sound channels appointment from quadro- to stereo playback along with turning of the sound source direction impression 90° to the left.

FIG. 9 shows the diagram how the device attends two separate rooms connected by corridor. Each room is provided with the appliance 7 for object (and loudspeakers) location recognition. So the whole area—both rooms and the corridor—are controlled by the devices 7.

Notation Conventions.

1—central station (for audio signal transmittance).

2—peripheral station, sound reproducing device (loudspeaker) for audio signal reception and playback,

3—listener (attended object),

4—control device for sounding mode appointment,

5—peer device,

6—base device,

6a—subordinate device,

7—object detection and location recognition appliance,

8—computing device for sound volume level calculation at the point of listener's (attended object) location,

9—computing device for data from devices 8 and 4 data examination and controlling data generation,

10—controlling tool for loudspeaker power control,

12—power supply unit,

13—network data exchange unit,

14—network,

15—large stationary objects (e.g., furniture).

### SUMMARY OF THE INVENTION

The declared technical result is achieved by using of the proposed method.

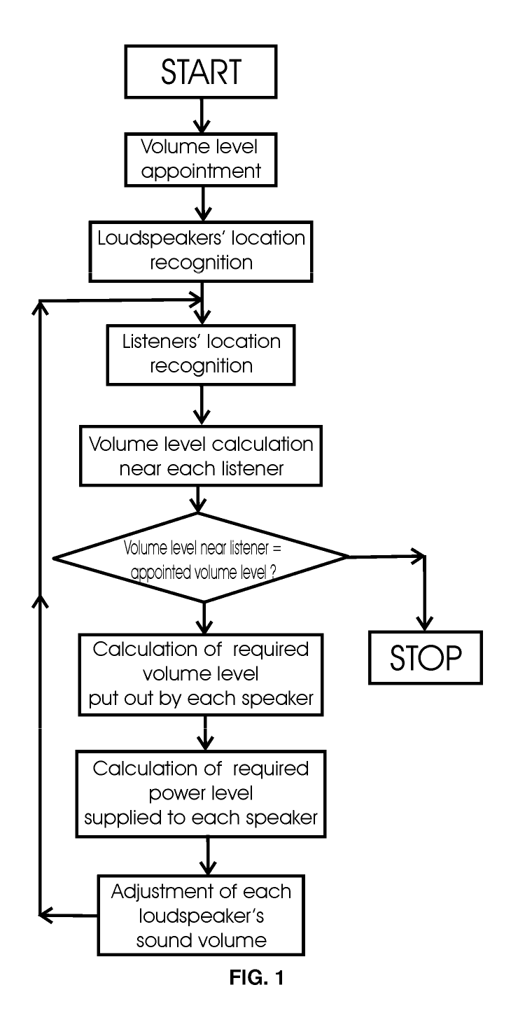

The proposed method of controlling of a plurality of sounding reproducing devices (FIG. 1) comprises the following steps.

Appointment of sound volume level to be provided for each listener throughout the area under control (room, hall, square, stadium).

Data reception about loudspeakers' location. The data can be obtained automatically from object recognition device or by manual input.

Data reception about listener's location (or an area of a plurality of listeners' location). The data can be obtained mainly automatically from object recognition device or by manual input if the listener does not move in the room.

Data calculation (by calculation device) about sound volume level at the point of listeners' location, taking into account each loudspeaker location in relation to location of the listener.

Comparison of this calculated sound volume level at listeners' location with the appointed one (by calculation device) and a correction data calculation, if necessary.

Sending of correction data to the control data generating tool.

Calculation (by calculation device) of the necessary volume level to be sounded by each loudspeaker.

Calculation (by calculation device) of corresponding output power level needed to achieve necessary volume level of each loudspeaker.

Adjustment of the calculated power level to the necessary level by each loudspeaker power control tool.

All calculating devices can be realized on the base of processor with RAM and ROM, input and output devices, corresponding software, or on the base of hardwired logic. The set devices and a complexity thereof depend on the required tasks.

The declared technical result can be achieved by using the proposed devices.

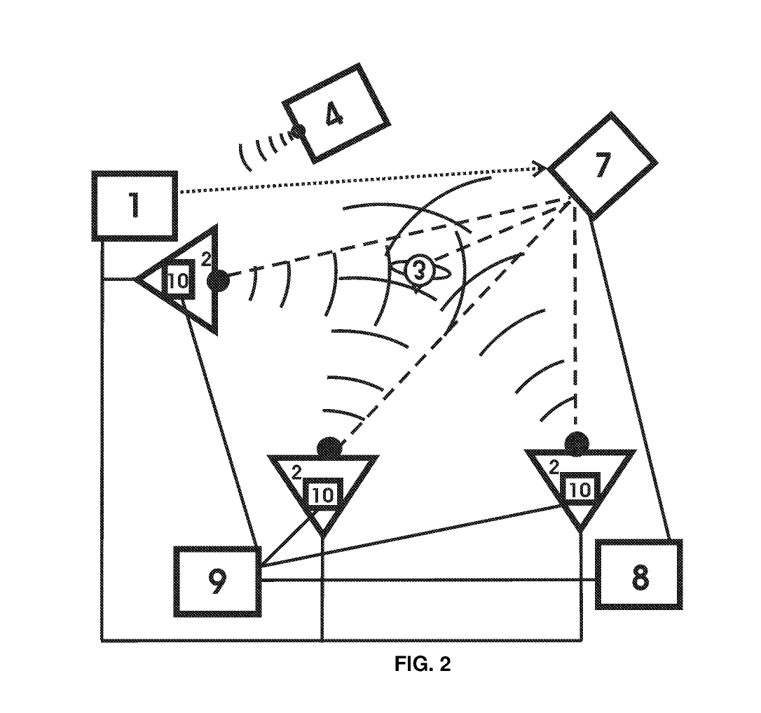

Sound reproducing system (FIG. 2) comprises the following components.

Sounding mode appointment device 4.

At least one central station 1 for audio signal transmittance.

One or more peripheral stations 2 for audio signal reception from said central station 1 and playback thereof.

Appliance 7 for object's (listeners and loudspeakers including) detection and location recognition.

Computing device 8 for performing audio signal parameters calculation at the point of listener's location (or in the nearest appointed neighborhood thereof).

Computing device 9 (computer) for performing calculation of tuning parameters (and parameters generation) for system tuning.

Loudspeaker 2 along with power controlling tool 10, commanded by the computing device 9 for calculation of tuning parameters for loudspeaker tuning.

The appliance for objects' (listener, loudspeakers, possibly other attended objects) detection and location recognition comprises the following devices.

One or more appliances 7 for location recognition and determination of location of one or more listeners 3, attended by the system, and peripheral stations 2.

One or more transmitting device for data transmission about listener's and peripheral stations' location.

One or more transmitting device for location data transmission about each listener and each peripheral station location data.

The computing device 8 for performing audio signal parameters calculation at the points of listener's location comprises at least the following devices:

receiving device for data receiving about listener's location, and sounding mode settings;

computing device for sound volume level calculation at the point of each listener's location;

transmitting device for sending results for peripheral stations working mode parameters calculation.

The device 9 (namely, computer) for performing calculation and system tuning for appointed sounding mode provision for each one of listeners comprises:

device for system sounding mode appointment (volume level and/or music impression spatial orientation including);

receiving device for data receiving about listener's (or listeners') and peripheral stations location;

computer device for peripheral stations working parameters calculation for the appointed sounding mode provision at the point of listener's location with a glance to peripheral stations location;

transmitting device for sending results as controlling data for peripheral stations tuning.

Data transmission between devices within the system can be performed by means of wired or wireless communication.

All separately realized devices can be joined into local area network.

In the case of hardware redundancy, devices—associates (participators) of the local network can themselves (automatically) assign performer for each required function.

Devices' control can be performed by means of local network.

Central 1 and peripheral 2 devices can be linked in a local network 14 and system components can be allocated to several (one or more) devices.

All system components except audio signal reception and volume control can be mounted on the central station—preferably, mobile device.

Components of the system can be tuned to achieve best spatial (three-dimensional) sound for listener.

Components of the system can be tuned to achieve the constant volume level in the assigned close neighborhood of the listener.

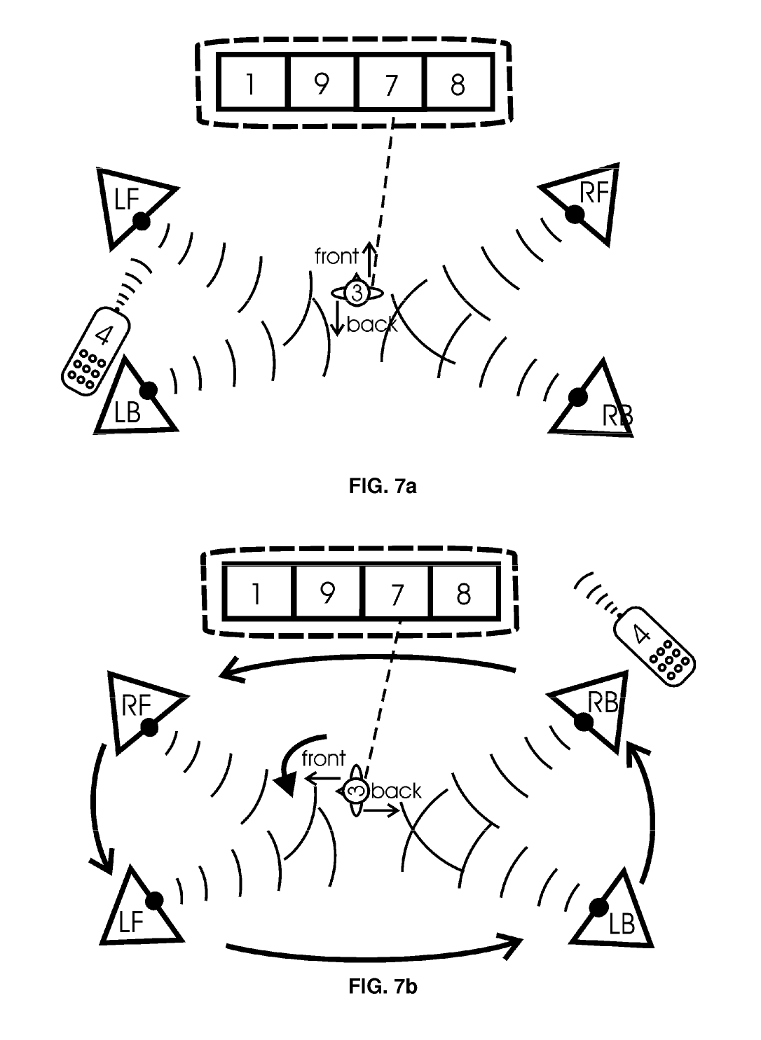

Components of the system can be tuned throughout the music piece play back to achieve constant sound sources' disposition impression regardless of listener's frontal direction. (FIGS. 7a, 7b).

System can use echolocation method for listener's and loudspeakers' location recognition.

System can use sounds of the played back audio piece as a source sound for echolocation for listener's and loudspeakers' location recognition.

System can use ultra wideband modulation (UWB) principle (method) for listeners' and loudspeakers' location recognition.

System can use angular-position method for listener's and loudspeakers' location recognition.

System can use sounds of the played audio piece as a source sound for angular-positioning for listeners and loudspeakers' location recognition.

Perceptible sound sources' main direction and spatial disposition of on default can be tuned at system setup.

Perceptible of sound sources' main direction and spatial disposition on default can be tuned automatically taking into account the system central and peripheral devices disposition.

Variant 1.

Solitary device (FIG. 2) comprises the following components.

a) Central station 1 for audio signal transmittance.

b) Sounding mode appointment device 4.

c) Appliance 7 for object (attended object, loudspeakers) detection and location recognition.

d) Device 8 for sound volume level calculation at the point of listener's (attended object's) location.

e) Calculating device 9 for data from the device 8 examination, calculation and controlling data generation.

f) Loudspeaker 2 along with controlling tool 10, commanded by the device 9.

g) Power supply unit 12.

Variant 2.

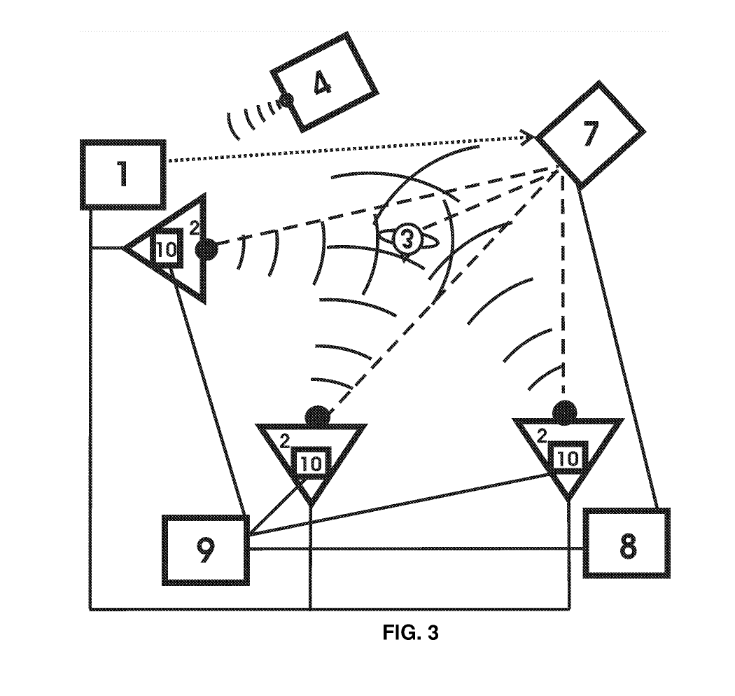

Cluster-type device (FIG. 3) comprises preferably one base device 6 and one or more, mainly a plurality of subordinate devices 6a and sounding mode appointment device 4.

Sounding mode appointment device 4 can be realized as separate device or composed with central or one of the peripheral stations.

The base device 6 can be realized and mounted as a free-standing, wall-hanged or mobile individual unit or as a device embedded in a sound reproducing device (loudspeaker).

In a case of composed device, it comprises base device units along with units, normally completing subordinate devices.

The base device 6 as a separate device comprises the following tools, devices and appliances.

a) Central station 1 for audio signal transmittance.

b) Appliance 7 for object location recognition.

c) Device 8 for sound volume level calculation at the point of each listener's location.

d) Device 9 for data from the devices 8 and 4 examination and controlling data generation.

e) Mainly network data exchange unit 13 for data exchange with subordinate appliances within the network 14.

f) Power supply unit 12.

Each subordinate appliance 6a comprises at least the following complete of devices and units.

a) Sound reproducing appliance 2 along with controlling tool 10, commanded by said data examination and controlling data generation appliance 9 via network data exchange unit 13.

b) Mainly network data exchange unit 13 for data exchange with base appliance within the network 14.

c) Power supply unit 12.

It optionally can comprise the following appliances.

d) Appliance 7 for object location detection.

e) Appliance 8 for sound volume level calculation.

f) Device 9 for data from devices 8 and 4 examination and generation of controlling data for loudspeakers.

Variant 3.

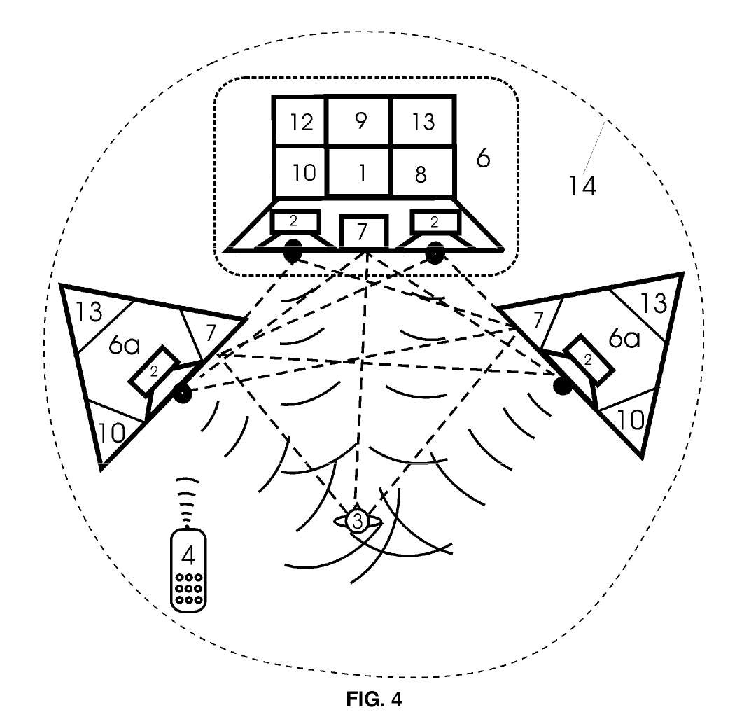

Cluster-type device (FIG. 4) comprises one or more, mainly a plurality of peer devices 5 and sounding mode appointment device 4.

Sounding mode appointment device 4 can be realized as separate device or composed with central or one of the peripheral stations.

The whole cluster-type device comprises the whole set of the following components (all set of components can be shared between constituent devices).

Each peer device 5 comprising one or more of the following devices so that the whole system totally comprises at least the following set of components.

a) Central station 1 for audio signal transmittance.

b) Appliance 7 for object location recognition.

c) Device 8 for sound volume level calculation at the point of each listener's location.

d) Device 9 for data from devices 8 and 4 examination and controlling data generation.

e) Controlling tool 10, commanded by the device 9, along with loudspeaker 2.

f) Mainly network data exchange unit 13 for data exchange with other devices within the network 14.

g) Power supply unit 12.

### DETAILED DESCRIPTION

The method of controlling of a plurality of loudspeakers comprises the following steps.

Appointment of sound volume level or sound playback mode to be provided for each listener 3 throughout the area under control (e.g. room, hall, square, stadium).

Definition of loudspeakers' location;

Definition of listeners' location.

Data calculation about sound volume level at listener's (or a plurality of listeners) location, taking into account each loudspeaker location and location of each listener 3.

Comparison of calculated sound volume level at listener's location with the appointed one and necessary correction data calculation.

Sending of the correction data to controlling data generating device.

Calculation of necessary volume level to be sounded by each loudspeaker.

Calculation of corresponding output power level needed to achieve necessary volume level of each loudspeaker;

Adjustment of current power level to the calculated necessary level by each loudspeaker power control tool 10.

Device realization variants.

Sound reproducing system (FIG. 2) comprises the following components.

Sounding mode assignment device 4.

At least one central station 1 for audio signal transmittance.

One or more peripheral stations 2 (loudspeakers) for audio signal reception from the central station 1 and playback thereof.

Appliance 7 for objects (attended objects, loudspeakers, and all other e.g. large stationary objects) location recognition.

Computing device 8 for performing audio signal parameters calculation at the points of listener's 3 location.

Computing device 9 for performing calculation and controlling data generation for system tuning for assigned sounding mode provision.

The peripheral stations 2 (loudspeakers) for audio signal reception comprises the following devices:
loudspeaking appliance for loud playback of audio signal;
one or more reception device for audio data reception;
one or more reception device for controlling data reception from appliance 9;
loudspeaker power control tool 10 for adjustment of current power level to the necessary level.

The appliance 7 for objects location recognition comprises the following devices:

one or more location recognition devices for one or more listeners 3 and peripheral stations 2 location recognition;

transmitting device for data transmission about location of listeners 3 and loudspeakers 2 (peripheral stations).

The computing device 8 for performing audio signal parameters calculation at the points of attended object's (listener's) location comprises:

receiving device for data receiving about listeners' location, sounding mode settings and loudspeakers 2 current mode;

computing device for sound volume level calculation at the point of each listener's location;

transmitting device for sending results for peripheral stations 2 working parameters calculation.

The device 9 (namely, computer) for performing calculation on the base of data from devices 8 and 4, system tuning for appointed sounding mode provision for each one of listeners comprises:

receiving device for reception data about listeners' location, calculation results from device 8, sounding mode appointment data;

computer device for peripheral stations 2 working parameters calculation for the appointed sounding mode provision at the points of listeners' location with a glance to the peripheral stations' location.

transmitting device for controlling data transmission for each peripheral station 2 working mode tuning.

Sounding mode can be of a various kinds—a constant volume of playback sound, a constant stereo effect (quadro-, spatial) impression regardless of man's location within the room (hall, area under control) including.

Data transmission between devices can be performed by means of wireless communication.

Data transmission appliance can be mountedone per each device. It can make transmission of all necessary data to all necessary recipients.

Data reception appliance can be mountedone per each device. It can receive of all necessary data from all necessary senders.

All separately realized devices can be joined into local network.

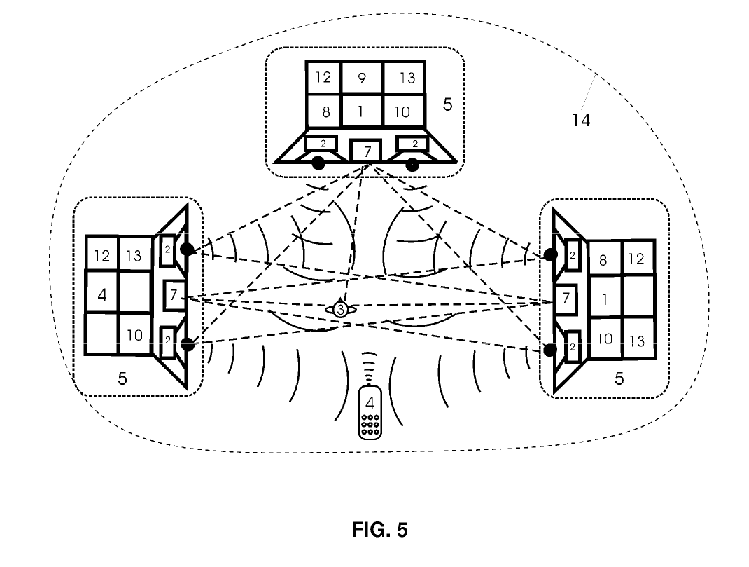

In the case of hardware redundancy devices—associates (participators) of the local network can themselves (automatically) assign performer for each of said required function (FIG. 5).

Devices' control can be performed by means of local network.

Central 1 and peripheral 2 devices can be linked in a local network 14, and system components are mounted on one or more devices within the system. System functions can be distributed between devices manually or automatically.

All system components except audio signal reception, power and volume control and speaker can be mounted on the central station 1—preferably, mobile device.

Components of the system can be tuned to achieve the best spatial sound for the listener.

Components of the system can be tuned to achieve the constant volume level in the assigned close neighborhood of the listener.

The system can be tuned throughout the music piece play back to achieve constant impression that the sound source is located directly in front of the listener regardless of the direction he turns his front.

System can use echolocation method for listeners' location recognition.

System can use sound of the played audio piece as a source sound during echolocation for listeners' and loudspeakers' location recognition.

System can use ultra wideband modulation (UWB) method for attended objects and loudspeakers location recognition.

System can use angular-position method for listeners' location recognition.

System can use sound of the played audio piece as a source sound during angular-positioning for listeners' and loudspeakers location recognition.

Sound source main direction and impression of its spatial disposition on default can be tuned at system setup.

Sound source main direction and impression of its spatial disposition on default can be tuned automatically taking into account the system central and peripheral devices disposition.

Variant 1.

Solitary device (FIG. 2) comprises the following components.

a) Sounding mode assignment device 4 (can be a separate mobile device).

b) At least one central station 1 for audio signal transmittance.

c) Appliance 7 for object detection.

d) Device 8 for sound volume level calculation at the point of listeners' location. The sound volume level calculation is performed on the base of known sounding volume produced by each loudspeaker, loudspeakers' location and the relative location of the attended object (listener).

e) Calculating device 9 for data from devices 8 and 4 examination, calculation and controlling data generation.

f) Loudspeaker 2 along with controlling tool 10, commanded by the appliance 9.

g) Power supply unit 12.

Variant 2.

Cluster-type device (FIG. 3) comprises preferably one base device 6 (central station 1 including) and mainly a plurality of subordinate devices 6a.

Sounding mode appointment device 4 can be realized as separate device or composed with central or one of the peripheral stations.

The base appliance 6 can be realized and mounted as a mobile, free-standing or wall-hanged (individual) unit or as a unit embedded in one of the loudspeakers. In a case of composed device, it comprises base device units along with units, normally completing subordinate appliances.

The base device comprises the following units and appliances.

a) Sounding mode assignment device 4 (can be a separate mobile device).

b) Central station 1 for audio signal transmittance.

c) Appliance 7 for object location recognition (listener and loudspeaker).

d) Device 8 for sound volume level calculation at the point of listener's location. The sound volume level calculation is performed on the base of known sounding volume produced by each loudspeaker, loudspeakers' location and the relative location of the listener. Large scale stationary objects (e.g. furniture) can also be taken into account.

c) Device 9 for data from devices 8 and 4 examination and generation of controlling data for loudspeakers.

d) Mainly network data exchange unit 13 for data exchange with subordinate appliances within the network 14.

e) Power supply unit 12.

Components of base device can be shared between subordinate devices. The only mandatory requirement is that all listed set of devices and appliances is to be present within the system.

Each subordinate appliance 6a can comprise a part of the abovementioned devices so that the whole system totally comprises at least the following set of components.

Each subordinate appliance 6a minimum mandatory set comprises (presuming that all other mandatory devices and appliances are mounted on other devices 5 within the system).

a) Loudspeaker 2 along with controlling tool 10, commanded by appliance 9.

b) Mainly network data exchange unit 13 for data exchange with base appliance within the network 14.

c) Power supply unit 12.

It optionally can comprise one or more of the following devices.

d) Appliance 7 for object detection.

e) Device 8 for sound volume level calculation (determination).

f) Device 9 for data from devices 8 and 4 examination and generation of controlling data for loudspeakers.

Variant 3.

Cluster-type device (FIG. 4) comprises one or more, mainly a plurality of peer devices 5.

The whole cluster-type device comprises at least the following set of components (all set of components can be shared between constituent devices).

a) Sounding mode assignment device 4 (can be a separate mobile device).

b) At least one central station 1 for audio signal transmittance.

c) Mainly network data exchange unit 13 for data exchange with other devices within the network 14.

d) Appliance 7 for object detection.

e) Device 8 for sound volume level calculation. The sound volume level calculation is performed on the base of known sounding volume produced by each loudspeaker, loudspeakers' location and the relative location of the attended object (listener). Large scale stationary objects (e.g. furniture) can also be taken into account.

f) Device 9 for data from devices 8 and 4 examination and controlling data generation.

g) Controlling tool 10, commanded by the device 9, along with loudspeaker 2.

h) f) Mainly network data exchange unit 13 for data exchange with other devices within the network 14.

i) g) Power supply unit 12.

Each peer device 5 can comprise a part of the above-mentioned devices so that the whole system totally comprises at least the following set of components.

Each device 5 minimum mandatory set comprises (presuming that all other mandatory devices and appliances are mounted on other devices 5 within the system).

j) Loudspeaker 2 along with power controlling tool 10, commanded by the appliance 9.

k) Mainly network data exchange unit 13 for data exchange with other devices within the network 14.

l) Power supply unit 12.

Appliance 7 for object recognition, can be realized on the base of optical (ultraviolet, infrared, and/or visible light photosensors, photo- or video camera), radio, ultra wideband modulation (UWB), acoustic radar, electro capacitive, mechanical and other principles. The appliance 7 principle selection depends upon required sensitivity, object minimal dimensions, requirements concerning metal details presence or absence therein, mounting ability on the floor, wall, price etc., climatic requirements and other factors.

Listener 3 can additionally comprise an active unit. Active unit can interact with the object detection appliance 7.

It is also supposed that the described sound reproducing system (loudspeaker) can be used either indoors, or outdoors.

Sound volume level calculation device 8 is mainly a computing device comprising processor, RAM, ROM, input and output devices, provided with algorithm (in the form of computer software) of sound volume attenuation degree calculation in free space conditions and in a presence of obstacles. It also calculates the sound volume level at the point of each listener's location, taking into account loudspeakers' location, sound volume level provided by each one of them and distance of each loudspeaker from the attended object. This volume level is then compared with the appointed volume level. In a case of not full correspondence thereof the device 8 sends control data to appliance 9 for volume level adjustment. The side noise can be also taken into account in the calculation by the device 8.

Device 9 for data analyzing, scenario developing and/or selection (from the set of preformed scenarios) and controlling data generation is mainly realized on the base of computer device with embedded programmable processor or on the base of hardwired logic, comprising memory units (ROM, RAM), peripheral input and output devices for external devices interaction via computer network including.

The computer hardware and software abilities selection for both appliances 8 and 9 depends on required productivity, production cost, operation efficiency, other factors.

Sound reproducing appliances 2 can be realized as stationary or mobile loudspeakers along with appropriate controlling tool 10. The main requirements to sound reproducing appliance are the sufficient power, sound frequency band and ability of gradually (continuously) adjustment of loudness. The loudspeaker can be either of diffused or directional sound. The controlled tool 10 provides gradual (continuous) intensity control of loudspeaker 2 in accordance with the controlling data (commands) of the data from devices 8 and 4 analysis and controlling data processing device 9. In a case of using the directional sound sources, the system should be additionally supplied with appropriate object tracking drive.

The power supply unit 12 can be either urban electricity network (mainly) or autonomous electric power supply sources, alternative and/or non-traditional including, for example, wind power stations, solar cells, fuel elements, other chemical, mechanical energy converters, radioisotope sources etc.

The network data exchange units 13 can use either separate dedicated line of any type known in the art, or wires of power supply network, or radio channel.

All kinds of appliance 7 can additionally comprise onto object direction determination appliance.

All kinds of appliance 7 can additionally comprise object distance calculation appliance.

For the noise-protection increase (elimination of distortion influence) the system can be supplied with coding appliance for output data encoding and decoding appliance for input data decoding.

All embodiments of the system can additionally comprise the volume level adjusting principle appliance. This volume level controlling principle of group or single sound speaking appliance, can provide the required volume level and a variety thereof in accordance with on-stream created scenario.

All embodiments of the system can additionally comprise the volume level adjusting appliance for example, in a presence of loud side noise.

All embodiments of the system can be supplied with the appliance that (in an autonomous mode) turns it to power economy mode in one or more preassigned time of a day or in accordance with other preassigned or calculated data.

All embodiments of the system can estimate the direction and/or distance to attended object and/or facing direction thereof via calculation using the object recognition appliance data.

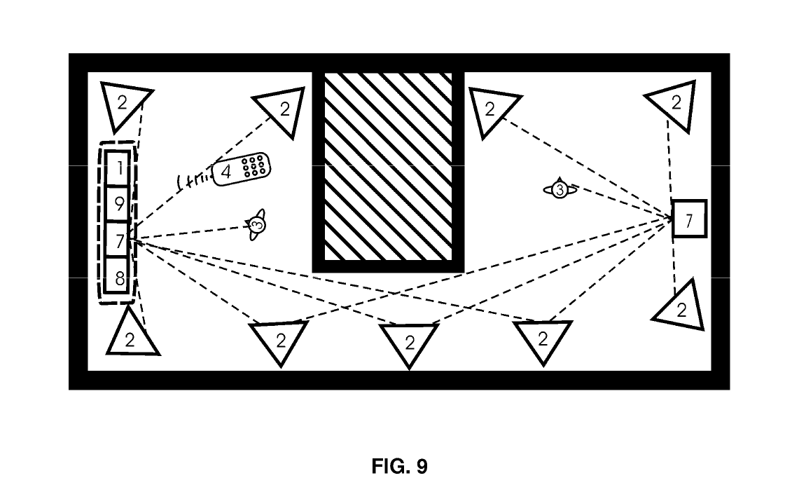

The controlling appliance 7 can control more than one attended object (listener). For example, if loudspeakers are located between two rooms (FIG. 9), then the area under control comprises two sub-areas that are both rooms. There are feasible variants of tracking several areas and attending listeners (persons) with the different status—loud volume area and low volume area.

The simultaneous attending of neighboring or adjacent areas and/or several separate areas by one system of cluster-type is also feasible. In this case each area must be provided with separate appliance 7 for object recognition (FIG. 9).

A joint operation of the system comprising devices described as variant 1 and/or variant 2, and/or variant 3 on the neighboring or adjacent areas under control is also feasible.

The proposed variant of the method consists in the following. Whole room is preliminarily investigated for presence and location of large stationary objects as furniture and the like (by appliance 7 for object recognition). These objects are further taken into account in sound loudness calculation. Additionally the entire system (preliminarily) determines the location of its components, and particularly sound producing devices (loudspeakers). Both mentioned operations can use sound echolocation. Echolocation can use sounds of played music as source sound. Mainly the first sounds at the moment of playback start can be used.

Also the system can use other principles for objects location determination: radiolocation, photo or video image recognition, ultrasonic location, UWB etc.

All data about large stationary subjects and system components location and sounding mode appointment is transferred to data examination and controlling data generation device 9.

Further, the system detects the presence of listeners within the area under control (room, hall etc.) (also by appliance 7 for object recognition).

The system can also determine the frontal orientation of the listener for providing identical stereo impression wherever the listener turns his front (FIGS. 7a, 7b). (i.e. the sound source direction impression turns following listener's frontal orientation.)

This can be provided by changing stereo- (or quadro-) playback parameters at light turns and changing the appointment of loudspeakers when the listener makes sizeable turns to different direction. For example, when he turns left 90′ the front-left speaker is reappointed to be front-right, front-right is reappointed to be back-right, back-right becomes back-left and so on. The system can do it continuously during the music playback. So the listener (e.g. attended object, a man) can move within the room, turn around, etc., and the system will provide him with music sounding of a constant volume and the impression that the sound source is always located in front of him, whatever direction he turns (FIG. 7).

The data examination and controlling data generation device 9 calculates the necessary volume to be produced by each loudspeaker to achieve the required total volume level at the point of the listener's location and sends controlling data to each power controlling tool 10 mainly mounted on the sound reproducing appliance 2. Each power controlling tool 10 tunes each corresponding sound reproducing appliance 2 so that the attended object receives the summarized played sound with the constant loudness and quality, regardless of his relocation.

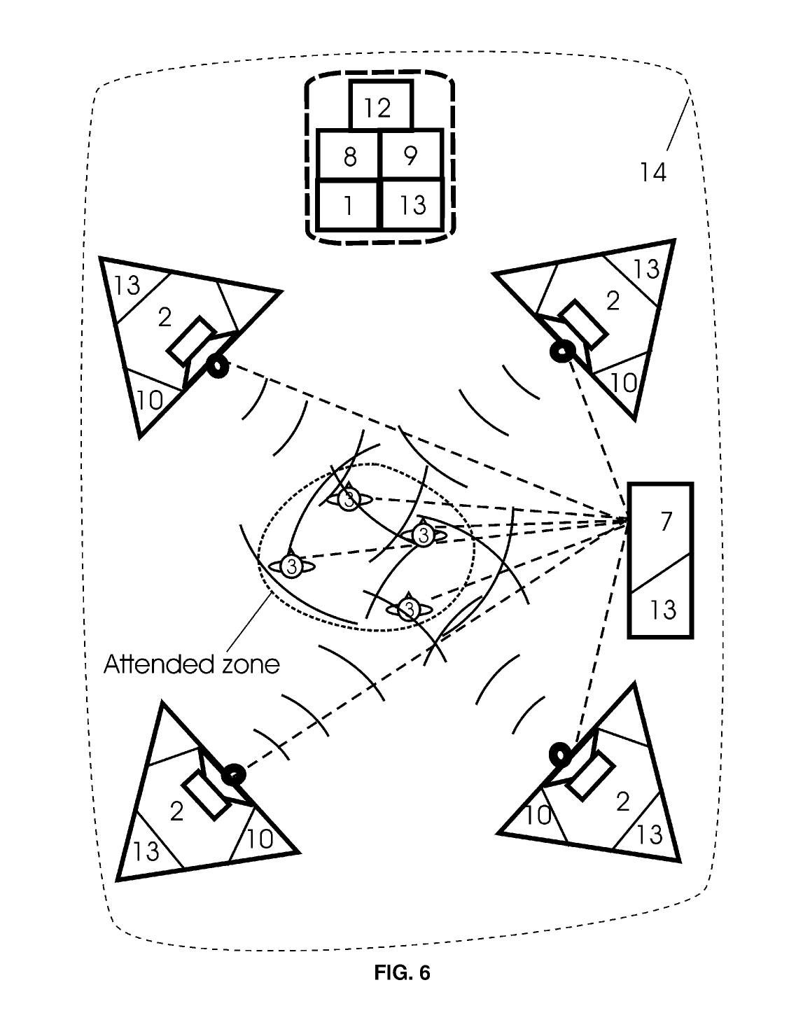

In the case of two or more listeners the device 9 attends not each object, but the center of a zone comprising and bounding them all (FIG. 6).

The appliance 7 for object recognition can operate in favor of several devices 8 and 9.

Appliance 7 can use sounds of played music as a source sounds for echolocation and reflection thereof continuously.

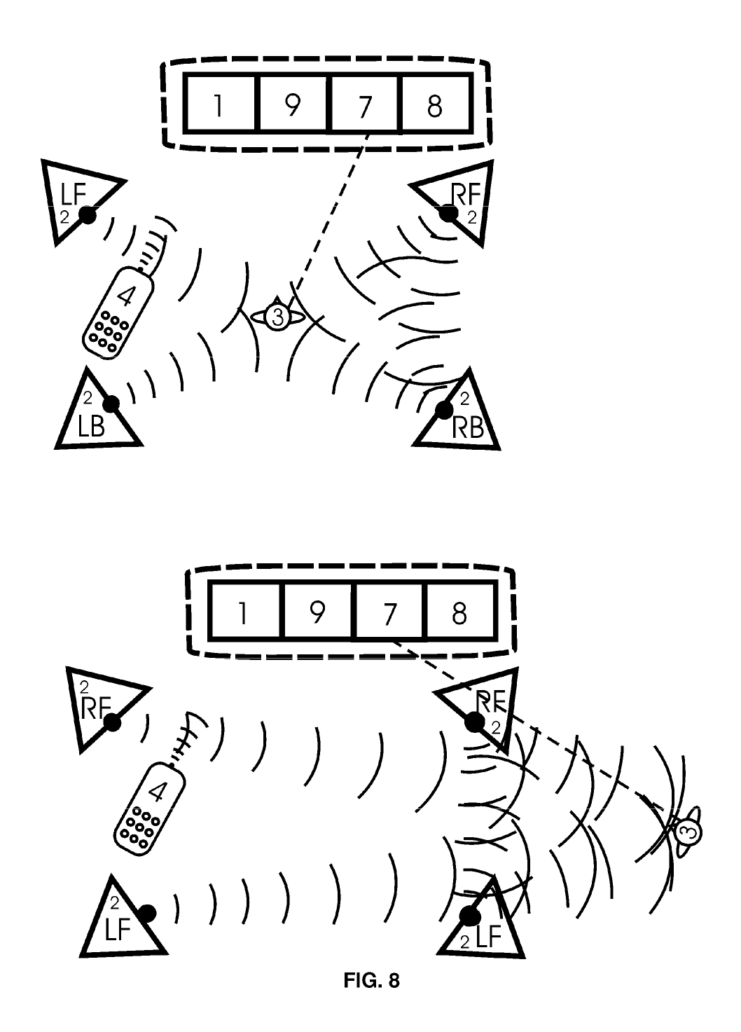

In a case when the listener walked out from the area bounded by loudspeakers the system re-appoints loudspeakers so that they act in stereo mode and they became right front or left front (or central) e.g. as shown in FIG. 8.

If the whole system is disposed in a plurality of separate rooms, connected by corridors, a plurality of object recognition appliances 7 are to be installed in the system because some loudspeakers and their tracked areas are not controlled by the sole appliance 7. The plurality of appliances 7 are to be located so that their areas under control intersect (see FIG. 9). In a case of one attended listener the system tunes the volume level exact as appointed within each room and in corridor and provides him with the impression that the sound source is always located in front of him, whatever direction he turns within each room.

Principle of Operation.

Variant 1.

Solitary sound reproducing device (FIG. 2).

The solitary device can be realized as an isolated device or consisting of group of devices (of the same type or together with devices described in variants 2 or 3) within the sound reproducing system. The device comprises full complete of devices and units necessary for autonomous operation.

The initial data list for system operating contains the volume level at the listener's location, large stationary subjects and system components location relatively to the loudspeakers. Other supplemental data can be added to the initial data list, for example, switching to economic mode time etc.

In a case of appearance of a listener 3 in the area under control (room, hall etc.), the object recognition appliance 7 generates a signal about a new object presence. The sound volume level calculation device 8 reveals the necessity of sound volume change at the point of new listener's 3 location. Data analysis and controlling data generation device 9 calculates data from devices 8 and 4 and generates the necessary control data for power control tool 10 which adjusts loudspeakers 2 to provide the necessary volume level exact as required.

After the listener 3 leaves the area under control (room, hall etc.) one or more of object detection appliances 7 generates a signal to stop attending this listener.

In a case of two or more simultaneously attended listeners 3, the volume level of each loudspeaker is maintained to provide the volume level in the tracked area center (bounding all attended objects together) to be exact as required level therefore. The volume level can be additionally limited depending on time of the day e.g. not higher than pre-assigned level.

Variant 2.

Cluster-type device (FIG. 3) comprising one base device 6 and one or more, mainly a plurality of subordinate devices 6a.

The device can be installed as an isolated group of devices or consisting of group of devices (of the same type or together with devices described in variants 1 or 3). The device comprises mainly one base device 6 and one or more subordinate devices 6a. The number of subordinate devices 6a in a group is limited only by the resources potential of the base device 6. The base device 6 can additionally comprise the subordinate device units complete.

The initial data list for device operation contains the volume level at the attended object location, large stationary subjects (system components including) location in relation to the loudspeaker. The other supplemental data can be added to initial data list, for example, switching to economic mode time, maximum admitted volume level, maximum number of simultaneously operating loudspeaker units around the attended object etc.

In a case of appearance of a listener 3 in the area under control (room), the object recognition appliance 7 (installed on the base device or one or more subordinate devices) generates a signal about a new listener's 3 presence and sends his location data to the base device of the group. The sound volume level calculation device 8 reveals the necessity of sound volume correction in the new listener's 3 location (or neighborhood thereof). Data analysis and controlling data generation device 9 calculates data from devices 8 and 4 and generates the necessary control data for power control tool 10 which adjusts sound reproducing units 2 to provide the necessary volume level exact as required.

After the listener 3 leaves the area under control (room) one or more of object recognition appliance 7 generates a signal to stop attending this listener.

In a case of two or more simultaneously attended listeners 3, the volume level of each loudspeaker is maintained to provide the volume level in the center of the tracked area bounding all attended objects exact as required therefore.

The volume level can be additionally limited depending on time of the day e.g. not higher than pre-assigned level.

The volume level can also be maintained to provide the required volume e.g. not higher than pre-assigned level therefore.

Variant 3.

Cluster-type device (FIG. 4) comprising one or more peer devices 5.

The device can be installed as an isolated single device or as an isolated group of devices or consisting of group of devices (of the same type or together with devices described in variants 1 or 2). The device comprises one more peer devices 5. The number of devices in a group is not limited.

The initial data list for device operation contains the volume level at the listener's location, large stationary subjects and system components location relatively to the loudspeakers. The other supplemental data can be added to the initial data list, for example, switching to economic mode time, maximum number of simultaneously operating loudspeaker units around the attended object etc.

This initial data can be stored in memory of one of the devices in group. The rest devices in the group can obtain this data via the network.

In a case of appearance of a listener 3 in the area under control (room), object recognition appliance 7 (of one or more devices) generates a signal about a new listener 3 presence and location to the rest devices of the group. The sound volume level calculation device 8 reveals the necessity of sound volume correction in the new attended object 3 location (or a neighborhood thereof). Data analysis and controlling data generation device 9 calculates data from devices 8 and 4 and generates the necessary control data for power control tool 10, which adjusts sound reproducing units 2 to provide the necessary volume level exact as required.

After the listener 3 leaves the area under control (room, hall) one or more of object recognition appliances 7 generates a signal to stop tracking this object.

In a case of two or more simultaneously attended listeners 3, the volume level of each loudspeaker is maintained to provide the volume level in the tracked area (mainly the center thereof) bounding all attended objects to be exact as required level therefore.

The volume level can be additionally limited depending on time of the day e.g. not higher than pre-assigned level.

The volume level can be maintained to provide the required volume e.g. to be exact as pre-assigned level therefore.

Additional notes regarding all variants of the disclosed system.

Data transmission between devices within the system can be performed by means of wired or wireless communication.

All separately realized devices can be joined into local area network.

In the case of hardware redundancy, devices—associates (participators) of the local network can themselves (automatically) assign performer for each required function.

Devices' control can be performed by means of local network.

Central 1 and peripheral 2 devices can be linked in a local network 14 and system components can be allocated to several (one or more) devices.

All system components except audio signal reception and volume control can be mounted on the central station or one of peer devices, or, preferably, mobile device.

Components of the system can be tuned to achieve best spatial (three-dimensional) sound for listener.

Components of the system can be tuned to achieve the constant volume level in the assigned close neighborhood of the listener.

Components of the system can be tuned throughout the music piece play back to achieve constant sound sources' disposition impression regardless of listener's frontal direction (FIGS. 7a, 7b).

System can use echolocation method for listener's and loudspeakers' location recognition.

System can use sounds of the played back audio piece as a source sound for echolocation for listener's and loudspeakers' location recognition.

System can use ultra wideband modulation (UWB) principle (method) for listeners' and loudspeakers' location recognition.

System can use angular-position method for listener's and loudspeakers' location recognition.

System can use sounds of the played audio piece as a source sound for angular-positioning for listeners and loudspeakers' location recognition.

Perceptible sound sources' main direction and spatial disposition of on default can be tuned at system setup.

Perceptible of sound sources' main direction and spatial disposition on default can be tuned automatically taking into account the system central and peripheral devices disposition.

Loudspeakers' disposition can be appointed manually by a particular switch or keyboard on the device case (body). It can be either device 9 or each loudspeaker 2.

Loudspeakers' disposition can be appointed automatically by object recognition appliances 7. In a case of sound location principle of operating thereof it can use a played back music sounds for revealing of each loudspeaker (i.e. peripheral station) 2 location.

Sound reproducing system can use sounds of the played back audio piece as a source sounds during angular-positioning of listeners and peripheral stations 2 location recognition.

Loudspeakers can be narrow-band emission devices, with the ability to direct emission of sound to the listener.

The method and devices are useful. It is industrially applicable as far as the whole complete or a part thereof can be made by industrial means.

1. Sound reproducing system comprising:
sounding mode appointment device 4;
one or more central station 1 for audio signal transmittance;
one or more peripheral stations 2 for audio signal reception from said central station and for playback thereof;
appliance 7 for object's location recognition;
computing device 8 for performing calculation of sounding parameters at the point of listener's location;
computing device 9 for performing calculation of tuning parameters and generating controlling data for sound reproducing appliances' tuning;
power control tool 10 for speaker 2 sounding parameters tuning in accordance with said tuning parameters;
power supply unit 12.

2. Sound reproducing system, as recited in claim 1, wherein said sounding mode appointment device 4 comprising
appliance for system sounding mode controlling data generation;
transmitting device for said controlling data transmission to said computing device for tuning parameters calculation and generating controlling data for sound reproducing appliances' tuning.

3. Sound reproducing system, as recited in claim 1, wherein said appliance 7 for object's location recognition comprising:
appliance for recognition the location of one or more objects, at least listeners and peripheral stations;
transmitting device for data transmission about objects location.

4. Sound reproducing system, as recited in claim 1, wherein said computing device 8 for performing calculation for loudspeakers tuning, comprises:
receiving device for receiving:
location data of listener and peripheral stations,
appointed sounding parameters,
computer device for sounding parameters calculating at the points of listener's location;
transmitting device for calculating results transmission.

5. Sound reproducing system, as recited in claim 1, wherein said computing device 9 for performing calculation and system tuning comprises:
receiving device for data receiving about sounding mode appointment, listener's and peripheral stations location, calculated sounding parameters at the points of listener's location;
computer device for peripheral stations working parameters calculation for the appointed sounding mode provision at the point of listener's location with a glance to peripheral stations location;
transmitting device for sending results as controlling data for peripheral stations tuning.

6. Sound reproducing system, as recited in any of the claims 1-4, wherein said data transmission between said devices is performed by means of wireless communication.

7. Sound reproducing system, as recited any of the claims 1-5, wherein said devices are joined into local network.

8. Sound reproducing system, as recited in claim 7, wherein in the case of hardware redundancy said devices—associates of said local network themselves automatically assign executing devices for each of required function.

9. Sound reproducing system, as recited in claim 7, wherein devices' control is performed via local network.

10. Sound reproducing system, as recited in any of the claims 1-4, wherein central and peripheral devices are linked in a local network and system components are mounted on one or more devices-associates.

11. Sound reproducing system, as recited in any of the claims 1-4, wherein all system components except audio signal reception and speaker power and volume control are mounted on the central station, preferably, mobile device.

12. Sound reproducing system, as recited in any of the claims 1-4, wherein components of the system are tuned to achieve best spatial sound for the listener.

13. Sound reproducing system, as recited in any of the claims 1-4, wherein components of the system are tuned to achieve the constant volume level at the point of listener's location.

14. Sound reproducing system, as recited any of the claims 1-4, wherein components of the system are being tuned throughout the music piece play back to achieve constant volumetric sound sources' disposition impression regardless of wherever attended listener turns his front.

15. Sound reproducing system, as recited in any of the claims 1-4, wherein the system uses echolocation method for listeners' and peripheral stations' location recognition.

16. Sound reproducing system, as recited in claim 15, wherein the system uses sounds of the played audio piece as a source sounds during echolocation for listeners' and peripheral stations' location recognition.

17. Sound reproducing system, as recited in any of the claims 1-4, wherein the system uses ultra wideband modulation method for listeners' location recognition.

18. Sound reproducing system, as recited in any of the claims 1-4, wherein the system uses angular-position method for listeners' and peripheral stations location recognition.

19. Sound reproducing system, as recited in claim 18, wherein the system uses sounds of the played back audio piece as a source sounds during angular-positioning for listeners' and peripheral stations' location recognition.

20. Sound reproducing system, as recited in any of the claims 1-4, wherein impression of sound sources' main direction and spatial disposition on default is tuned at system setup.

21. Sound reproducing system, as recited in any of the claims 1-4, wherein impression of sound sources' main direction and spatial disposition on default is tuned automatically taking into account said central and peripheral devices relative disposition.

22. Solitary sound reproducing system comprising at least the following devices:
device for sounding mode appointment;
central station for audio signal transmittance;
appliance for objects' location recognition;
computing device for performing calculation of sounding parameters at the points of each listener's location;
computing device for performing calculation of tuning parameters for system tuning for appointed sounding mode provision;
power control tool for speaker sounding parameters tuning in accordance with said tuning parameters;
power supply unit.

23. Cluster-type sound reproducing system, comprising at least one base device and one or more subordinate devices, said base device further comprising all or a part of the following units:
appliance for sounding mode appointment;
central station for audio signal transmittance;
appliance for objects' location recognition, at least one for the whole area under control;
computing device for performing calculation of sounding parameters at the point of listener's location, at least one for the whole system;
computing device for performing calculation of tuning parameters for system tuning for appointed sounding mode provision, at least one for the whole system;
power control tool for speaker sounding parameters tuning in accordance with said accepted tuning parameters;
mainly network unit for network connection and data exchange with said subordinate devices within the network;
power supply unit,
said subordinate device further comprising all or part of the following mandatory units:
power control tool for speaker sounding parameters tuning in accordance with said accepted tuning parameters;
mainly network unit for network connection and data exchange with said subordinate devices within the network;
power supply unit,
said subordinate device further optionally comprising all or part of the following units:
appliance for objects' location recognition, at least one for the whole area under control;
computing device for performing calculation concerning sounding parameters at the points of each listener's location, at least one for the whole system;
computing device for performing calculation of tuning parameters for system tuning for appointed sounding mode provision, at least one for the whole system.

24. Cluster-type sound reproducing system, comprising one or more peer devices, said each peer device further comprising all or a part of the following components so that the whole system comprises all set thereof:
appliance for sounding mode assignment;
central station for audio signal transmittance;
appliance for objects' location recognition, at least one for the whole area under control;
computing device for performing calculation concerning sounding parameters at the points of each listener's location, at least one for the whole system;
computing device for performing calculation of tuning parameters for system tuning for appointed sounding mode provision, at least one for the whole system;
power control tool for speaker sounding parameters tuning in accordance with said tuning parameters;
mainly network unit for network connection and data exchange with said subordinate devices within the network;
power supply unit.

25. Sound reproducing system as recited in any of the claims 1, 22, 22, 23, wherein said power supply unit is a local autonomous power supply unit.

26. Sound reproducing system, as recited in any of the claims 1, 22, 23, 24, wherein said power supply unit is an urban electricity network power supply.

27. Sound reproducing system as recited in any of the claims 1, 22, 23, 24, further comprising scenario launching device for launching scenario of volume control mode as well as playback channels appointment mode for groups or solitary loudspeakers,
said scenario preliminarily made or created in the course of playback, in accordance with said appointed sounding volume mode and playback channels appointment mode,
said scenario launching device for cumulative volume level control, providing required volume level and audio parameters values.

28. Sound reproducing system as recited in any of the claims 1, 22, 23, 24, further comprising device for switching the whole system, working in the autonomous mode, to economy mode one or more times a day.

29. Sound reproducing system as recited in any of the claims 1, 22, 23, 24, wherein said appliance for listeners' location recognition is a motion detector.

30. Sound reproducing system as recited in any of the claims 1, 22, 23, 24, wherein the system controls more than one area simultaneously.

31. Sound reproducing system as recited in any of the claims 1, 22, 23, 24, wherein said loudspeakers are narrow-band emission devices.

32. Sound reproducing system as recited in any of the claims 1, 22, 23, 24, wherein said playback device along with said volume control device further comprising device for acoustic emission direction change.

33. Sound reproducing system as recited in any of the claims 1, 22, 23, 24, wherein said sound reproducing units' location is appointed manually by a particular switch or keyboard on the device body.

34. Sound reproducing system as recited in any of the claims 1, 22, 23, 24, wherein said loudspeakers' disposition is appointed automatically by said object location recognition appliances.

35. Sound reproducing system as recited in claim 34, wherein said object location recognition appliance can use a played music sounds as a source for revealing of each loudspeaker location.

36. Sound reproducing system as recited in claim 34, wherein said volume level in a preliminarily assigned neighborhood of listener is examined by said calculating appliance 9 and object location recognition appliance 7.

37. Sound reproducing system as recited in claim 34, wherein said object location recognition appliance 7 uses echolocation principle.

38. Sound reproducing system as recited in claim 34, wherein said object location recognition appliance uses ultra wideband modulation (UWB).

39. Sound reproducing system as recited in claim 34, wherein said attended object additionally comprise an active unit which can interact with said object detection appliance.

40. Method of controlling of a plurality of loudspeakers comprises:
appointment of sound playback mode to be provided for one or more listeners throughout the area under control;
data reception about loudspeakers' location;
data reception about all said listeners' location;
data calculation about sound volume level at listeners' location, taking into account each loudspeaker's location and location of said listener;
comparison of said calculated sound volume level at listeners' location with the appointed one and a correction data calculation, if necessary;
sending of said correction data to control data generating device;
calculation of the necessary volume level to be sounded by each loudspeaker;
calculation of corresponding output power level required to achieve necessary volume level of each loudspeaker;
adjustment of the calculated power level by each loudspeaker power control tool.
